(19) United States
(12) Patent Application Publication
(10) Pub. No.: US 2024/0250026 A1
(43) Pub. Date: Jul. 25, 2024

(54) SEMICONDUCTOR MEMORY DEVICE

(71) Applicant: Kioxia Corporation, Tokyo (JP)

(72) Inventor: Nobuaki OKADA, Kawasaki Kanagawa (JP)

(73) Assignee: Kioxia Corporation, Tokyo (JP)

(21) Appl. No.: 18/596,742

(22) Filed: Mar. 6, 2024

Related U.S. Application Data
(63) Continuation of application No. PCT/JP2021/044163, filed on Dec. 1, 2021.

(30) Foreign Application Priority Data
Sep. 21, 2021 (JP) 2021-153402

(51) Int. Cl. H01L 23/528; G11C 16/04; G11C 16/30; H01L 23/522; H01L 25/065; H10B 41/10; H10B 41/27; H10B 41/40; H10B 43/10; H10B 43/27; H10B 43/40; H10B 80/00

(52) U.S. Cl. CPC H01L 23/5283; G11C 16/0483; G11C 16/30; H01L 23/5223; H01L 23/5226; H01L 25/0657; H10B 41/10; H10B 41/27; H10B 41/40; H10B 43/10; H10B 43/27; H10B 43/40; H10B 80/00; H01L 2225/06506

(57) ABSTRACT

A semiconductor memory device includes: a substrate; a first wiring layer including a first conductive layer and a second conductive layer; a second wiring layer disposed between the substrate and the first wiring layer; and a memory cell array layer disposed between the substrate and the second wiring layer. The memory cell array layer includes: a plurality of third conductive layers arranged in a first direction intersecting with a surface of the substrate; a semiconductor layer extending in the first direction and opposed to the plurality of third conductive layers; and an electric charge accumulating layer disposed between the plurality of third conductive layers and the semiconductor layer. The second wiring layer includes: a fourth conductive layer connected to one end portion of the semiconductor layer in the first direction; and a fifth conductive layer opposed to the first conductive layer and electrically connected to the second conductive layer.

### CROSS-REFERENCE TO RELATED APPLICATIONS

This is a continuation application of PCT International Application No. PCT/JP2021/044163 filed on Dec. 1, 2021, designating the United States of America, which is based on and claims priority of Japanese Patent Application No. 2021-153402 filed on Sep. 21, 2021. The entire disclosures of the above-identified applications, including the specifications, drawings and claims are incorporated herein by reference in their entirety.

### BACKGROUND

### Field

Embodiments described herein relate generally to a semiconductor memory device.

### Description of the Related Art

There has been known a semiconductor memory device including a substrate, a plurality of conductive layers arranged in a first direction intersecting with a surface of the substrate, a semiconductor layer extending in the first direction and opposed to the plurality of conductive layers, and an electric charge accumulating layer disposed between the plurality of conductive layers and the semiconductor layer.

### BRIEF DESCRIPTION OF THE DRAWINGS

FIG. 1 is a schematic block diagram illustrating a configuration of a semiconductor memory device according to a first embodiment;

FIG. 2 is a schematic side view illustrating an exemplary configuration of the semiconductor memory device;

FIG. 3 is a schematic plan view illustrating an exemplary configuration of the semiconductor memory device;

FIG. 4 is a schematic block diagram illustrating an exemplary configuration of the semiconductor memory device;

FIG. 5 is a schematic circuit diagram illustrating a configuration of a part of the semiconductor memory device;

FIG. 6 is a schematic circuit diagram illustrating a configuration of a part of the semiconductor memory device;

FIG. 7 is a schematic circuit diagram illustrating a configuration of a part of the semiconductor memory device;

FIG. 8 is a schematic circuit diagram illustrating a configuration of a part of the semiconductor memory device;

FIG. 9 is a schematic perspective view illustrating a configuration of a part of the semiconductor memory device;

FIG. 10 is a schematic bottom view illustrating a configuration of a part of the semiconductor memory device;

FIG. 11 is a schematic plan view illustrating a configuration of a part of the semiconductor memory device;

FIG. 12 is a schematic cross-sectional view corresponding to a line A1-A1′ of FIG. 10 and a line B1-B1′ of FIG. 11;

FIG. 13 is a schematic cross-sectional view corresponding to a line A2-A2′ of FIG. 10 and a line B2-B2′ of FIG. 11;

FIG. 14 is a schematic cross-sectional view illustrating a configuration of a part of the semiconductor memory device;

FIG. 15 is a schematic cross-sectional view illustrating a configuration of a part of the semiconductor memory device;

FIG. 16 is a schematic cross-sectional view and a plan view illustrating a configuration of a part of the semiconductor memory device;

FIG. 17 is a schematic plan view illustrating a configuration of a part of a semiconductor memory device according to Modification 1 of the first embodiment;

FIG. 18 is a schematic plan view illustrating a configuration of a part of a semiconductor memory device according to Modification 2 of the first embodiment;

FIG. 19 is a schematic plan view illustrating a configuration of a part of a semiconductor memory device according to Modification 3 of the first embodiment;

FIG. 20 is a schematic plan view illustrating a configuration of a part of a semiconductor memory device according to Modification 4 of the first embodiment;

FIG. 21 is a schematic cross-sectional view illustrating a configuration of a part of a semiconductor memory device according to a second embodiment;

FIG. 22 is a schematic cross-sectional view and a plan view illustrating a configuration of a part of the semiconductor memory device;

FIG. 23 is a schematic cross-sectional view illustrating a configuration of a part of a semiconductor memory device according to a third embodiment;

FIG. 24 is a schematic cross-sectional view illustrating a configuration of a part of a semiconductor memory device according to another embodiment; and

FIG. 25 is a schematic cross-sectional view illustrating a configuration of a part of a semiconductor memory device according to another embodiment.

### DETAILED DESCRIPTION

A semiconductor memory device according to one embodiment comprises: a substrate; a first wiring layer including a first conductive layer and a second conductive layer; a second wiring layer disposed between the substrate and the first wiring layer; and a memory cell array layer disposed between the substrate and the second wiring layer. The memory cell array layer includes: a plurality of third conductive layers arranged in a first direction intersecting with a surface of the substrate; a semiconductor layer extending in the first direction and opposed to the plurality of third conductive layers; and an electric charge accumulating layer disposed between the plurality of third conductive layers and the semiconductor layer. The second wiring layer includes: a fourth conductive layer connected to one end portion of the semiconductor layer in the first direction; and a fifth conductive layer opposed to the first conductive layer and electrically connected to the second conductive layer.

Next, the semiconductor memory devices according to embodiments are described in detail with reference to the drawings. The following embodiments are only examples, and not described for the purpose of limiting the present invention.

In this specification, when referring to a “semiconductor memory device”, it may mean a memory die (memory chip) and may mean a memory system including a controller die, such as a memory card and an SSD. Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a

Scanning electron microscopy (SEM), a Transmission electron microscopy (TEM), or the like.

### First Embodiment

### Memory System 10

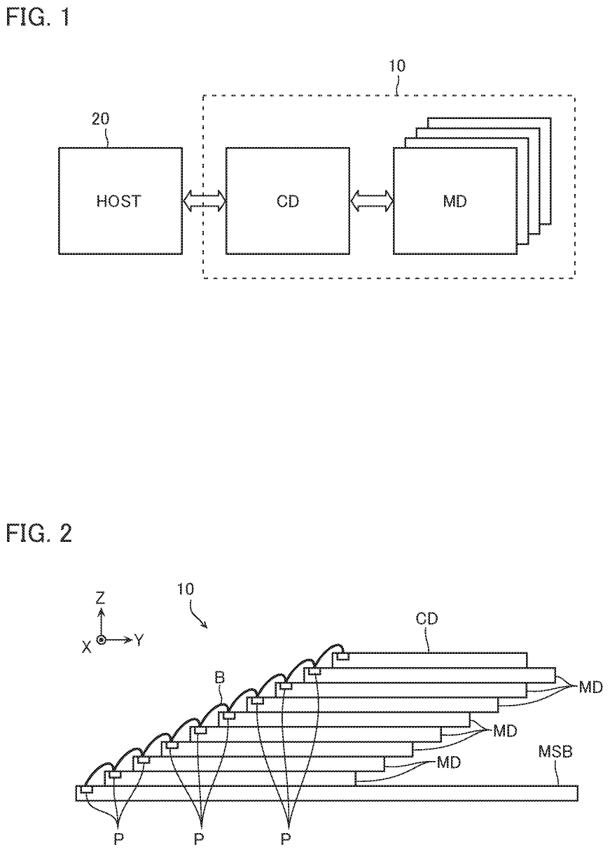

FIG. 1 is a schematic block diagram illustrating a configuration of a memory system 10 according to the first embodiment.

The memory system 10, for example, reads, writes, and erases user data according to a signal transmitted from a host computer 20. The memory system 10 is, for example, any system that can store the user data including a memory card and an SSD. The memory system 10 includes a plurality of memory dies MD that store the user data and a controller die CD connected to these plurality of memory dies MD and the host computer 20. The controller die CD includes, for example, a processor, a RAM, and the like, and performs conversion between a logical address and a physical address, bit error detection/correction, a garbage collection (compaction), a wear leveling, and the like.

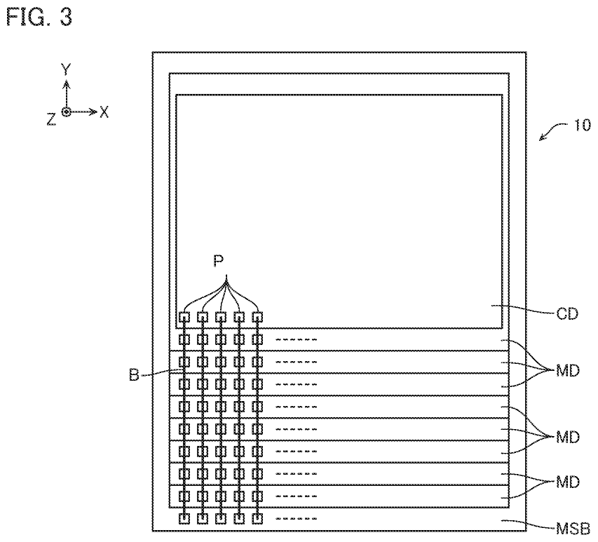

FIG. 2 is a schematic side view illustrating an exemplary configuration of the memory system 10 according to the embodiment. FIG. 3 is a schematic plan view illustrating the exemplary configuration. For convenience of explanation, a part of the configuration is omitted in FIG. 2 and FIG. 3.

As illustrated in FIG. 2, the memory system 10 according to the embodiment includes a mounting substrate MSB, the plurality of memory dies MD stacked on the mounting substrate MSB, and the controller die CD stacked on the memory die MD. On an upper surface of the mounting substrate MSB, a pad electrode P is disposed in a region at an end portion in the Y-direction, and a part of the other region is bonded to a lower surface of the memory die MD via an adhesive and the like. On an upper surface of the memory die MD, the pad electrode P is disposed in a region at an end portion in the Y-direction, and the other region is bonded to a lower surface of another memory die MD or the controller die CD via the adhesive and the like. On an upper surface of the controller die CD, the pad electrode P is disposed in a region at an end portion in the Y-direction.

As illustrated in FIG. 3, the mounting substrate MSB, the plurality of memory dies MD, and the controller die CD each include a plurality of pad electrodes P arranged in the X-direction. The plurality of pad electrodes P disposed on each of the mounting substrate MSB, the plurality of memory dies MD, and the controller die CD are mutually connected via bonding wires B.

Note that the configuration illustrated in FIG. 2 and FIG. 3 is merely an example, and specific configurations are appropriately adjustable. For example, in the example illustrated in FIG. 2 and FIG. 3, the controller die CD is stacked on the plurality of memory dies MD, and these configurations are connected with the bonding wires B. In such a configuration, the plurality of memory dies MD and the controller die CD are included in one package.

However, the controller die CD may be included in a package different from the memory die MD. Additionally, the plurality of memory dies MD and the controller die CD may be connected to one another via through electrodes or the like, not the bonding wires B.

### Circuit Configuration of Memory Die MD

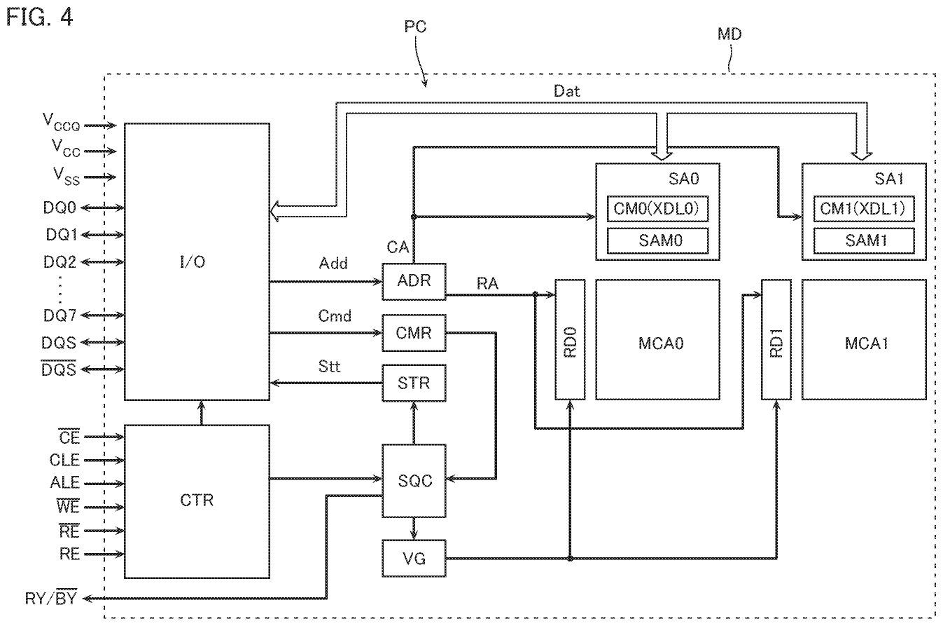

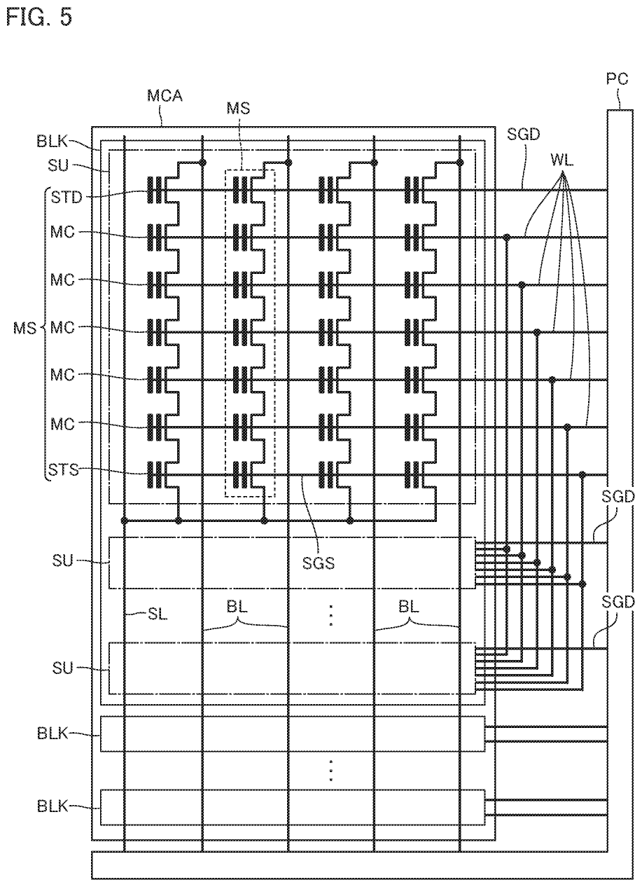

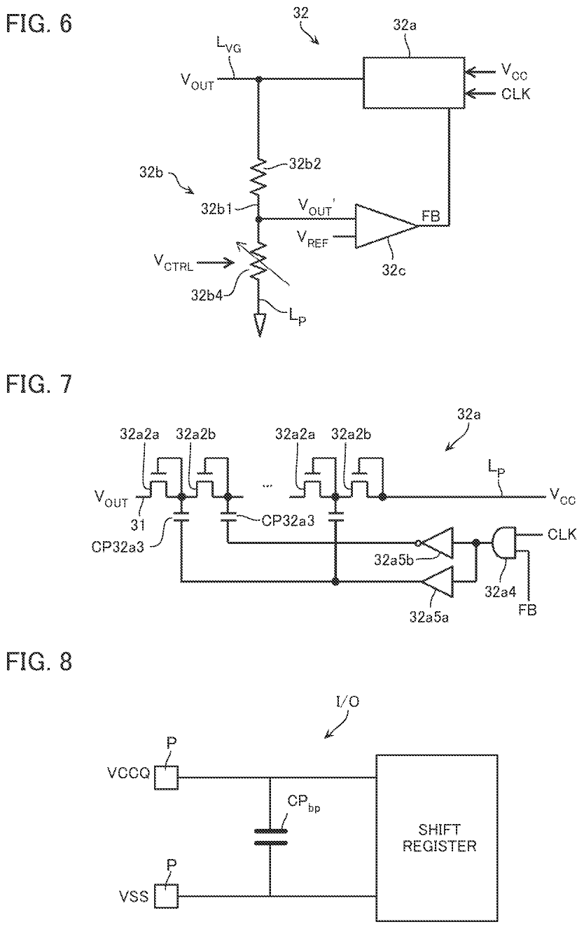

FIG. 4 is a schematic block diagram illustrating a configuration of the memory die MD according to the first embodiment. FIG. 5 is a schematic circuit diagram illustrating a configuration of a part of the memory die MD. FIG. 6 and FIG. 7 are schematic circuit diagrams illustrating configurations of parts of a voltage generation circuit described later. FIG. 8 is a schematic circuit diagram illustrating a configuration of a part of an input/output control circuit I/O described later. For convenience of explanation, a part of the configuration is omitted in FIG. 4 to FIG. 8.

FIG. 4 illustrates a plurality of control terminals and the like. These plurality of control terminals are represented as control terminals corresponding to a high active signal (positive logic signal) in some cases, represented as control terminals corresponding to a low active signal (negative logic signal) in some cases, and represented as control terminals corresponding to both the high active signal and the low active signal in some cases. In FIG. 4, a reference sign of the control terminal corresponding to the low active signal includes an over line (overbar). In this specification, a reference sign of the control terminal corresponding to the low active signal includes a slash (“/”). The description of FIG. 4 is an example, and specific aspects are appropriately adjustable. For example, a part of or all of the high active signals can be changed to the low active signals, or a part of or all of the low active signals can be changed to the high active signals.

As illustrated in FIG. 4, the memory die MD includes memory cell arrays MCA0, MCA1 storing the user data, and a peripheral circuit PC connected to the memory cell arrays MCA0, MCA1. In the following description, the memory cell arrays MCA0, MCA1 are referred to as a memory cell array MCA in some cases.

### Circuit Configuration of Memory Cell Array MCA

As illustrated in FIG. 5, the memory cell array MCA includes a plurality of memory blocks BLK. Each of these plurality of memory blocks BLK includes a plurality of string units SU. Each of these plurality of string units SU includes a plurality of memory strings MS. Each of these plurality of memory strings MS has one end connected to the peripheral circuit PC via a bit line BL. Each of these plurality of memory strings MS has the other end connected to the peripheral circuit PC via a common source line SL.

The memory string MS includes a drain-side select transistor STD, a plurality of memory cells MC (memory cell transistors), and a source-side select transistor STS, which are connected in series between the bit line BL and the source line SL. Hereinafter, the drain-side select transistor STD and the source-side select transistor STS are simply referred to as select transistors (STD, STS) in some cases.

The memory cell MC is a field-effect type transistor that includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC usually stores the user data of one bit or a plurality of bits. Respective word lines WL are connected to the gate electrodes of the plurality of memory cells MC corresponding to one memory string MS. Each of these word lines WL is connected to all the memory strings MS in one memory block BLK in common.

The select transistors (STD, STS) are field-effect type transistors that each include a semiconductor layer, a gate insulating film, and a gate electrode. The semiconductor layer functions as a channel region. A drain-side select gate line SGD and a source-side select gate line SGS are connected to gate electrodes of the select transistors (STD, STS), respectively. The drain-side select gate line SGD is disposed corresponding to the string unit SU and is connected in common to all the memory strings MS in one string unit SU. The source-side select gate line SGS is connected in common to all the memory strings MS in the memory block BLK. Hereinafter, the drain-side select gate line SGD and the source-side select gate line SGS are simply referred to as select gate lines (SGD, SGS) in some cases.

### Circuit Configuration of Peripheral Circuit PC

For example, as illustrated in FIG. 4, the peripheral circuit PC includes row decoders RD0, RD1 and sense amplifiers SA0, SA1 connected to the memory cell arrays MCA0, MCA1, respectively. The peripheral circuit PC includes a voltage generation circuit VG and a sequencer SQC. The peripheral circuit PC includes the input/output control circuit I/O, a logic circuit CTR, an address register ADR, a command register CMR, and a status register STR. In the following description, the row decoders RD0, RD1 are referred to as a row decoder RD, and the sense amplifiers SA0, SA1 are referred to as a sense amplifier SA in some cases.

### Configuration of Row Decoder RD

The row decoder RD includes, for example, a decode circuit and a switch circuit. The decode circuit decodes a row address RA stored in the address register ADR. The switch circuit electrically conducts the word line WL and the select gate lines (SGD, SGS) corresponding to the row address RA with corresponding voltage supply lines in accordance with an output signal of the decode circuit.

### Configuration of Sense Amplifier SA

The sense amplifiers SA0, SA1 (FIG. 4) include sense amplifier modules SAM0, SAM1 and cache memories CM0, CM1 (data registers), respectively. The cache memories CM0, CM1 include latch circuits XDL0, XDL1, respectively.

In the following description, the sense amplifier modules SAM0, SAM1 are referred to as a sense amplifier module SAM, the cache memories CM0, CM1 are referred to as a cache memory CM, and the latch circuits XDL0, XDL1 are referred to as a latch circuit XDL, in some cases.

Each of the plurality of latch circuits XDL is connected to a latch circuit in the sense amplifier module SAM. In the latch circuit XDL, for example, the user data written to the memory cell MC or the user data read from the memory cell MC is stored.

For example, a column decoder is connected to the cache memory CM. The column decoder decodes a column address CA stored in the address register ADR (FIG. 4) and selects the latch circuit XDL corresponding to the column address CA.

The user data Dat included in these plurality of latch circuits XDL are sequentially transferred to the latch circuits inside the sense amplifier modules SAM in a write operation. The user data Dat included in the latch circuits inside the sense amplifier modules SAM are sequentially transferred to the latch circuits XDL in a read operation. The user data Dat included in the latch circuits XDL are sequentially transferred to the input/output control circuit I/O in a data-out operation.

### Configuration of Voltage Generation Circuit VG

The voltage generation circuit VG (FIG. 4) includes, for example, a step down circuit, such as a regulator, and a step up circuit, such as a charge pump circuit 32 (FIG. 6). These step down circuit and step up circuit are each connected to the voltage supply line to which a power supply voltage V_{CC} and a ground voltage V_{SS} (FIG. 4) are applied. These voltage supply lines are connected to, for example, the pad electrodes P described with reference to FIG. 2 and FIG. 3. For example, the voltage generation circuit VG generates a plurality of operating voltages applied to the bit line BL, the source line SL, the word line WL, and the select gate lines (SGD, SGS) in the read operation, the write operation, and an erase operation on the memory cell array MCA in response to the control signal from the sequencer SQC and simultaneously outputs the operating voltages to the plurality of voltage supply lines. The operating voltage output from the voltage supply line is appropriately adjusted in response to the control signal from the sequencer SQC.

For example, as illustrated in FIG. 6, the charge pump circuit 32 includes a voltage output circuit 32a, a voltage dividing circuit 32b, and a comparator 32c. The voltage dividing circuit 32b is connected to a voltage supply line L_{VG}. The comparator 32c outputs a feedback signal FB to the voltage output circuit 32a according to a magnitude relation between a voltage V_{OUT}′ output from the voltage dividing circuit 32b and a reference voltage V_{REF}.

As illustrated in FIG. 7, the voltage output circuit 32a includes a plurality of transistors 32a2a, 32a2b. The plurality of transistors 32a2a, 32a2b are alternately connected between the voltage supply line L_{VG} and a voltage supply line L_{P}. The illustrated voltage supply line L_{P} is applied with the power supply voltage V_{CC}. Gate electrodes of the plurality of transistors 32a2a, 32a2b connected in series are connected to their respective drain electrodes and capacitive elements CP32a3. The voltage output circuit 32a includes an AND circuit 32a4, a level shifter 32a5a, and a level shifter 32a5b. The AND circuit 32a4 outputs a logical disjunction of a clock signal CLK and the feedback signal FB. The level shifter 32a5a steps up the output signal of the AND circuit 32a4 and outputs it. The level shifter 32a5a includes an output terminal connected to the gate electrode of the transistor 32a2a via the capacitive element CP32a3. The level shifter 32a5b steps up an inverted signal of the output signal of the AND circuit 32a4 and outputs it. The level shifter 32a5b includes an output terminal connected to the gate electrode of the transistor 32a2b via the capacitive element CP32a3.

When the feedback signal FB is in an “H” state, the AND circuit 32a4 outputs the clock signal CLK. In response to this, the electrons are transferred from a voltage supply line 31 to the voltage supply line L_{P}, and the voltage of the voltage supply line 31 increases. Meanwhile, when the feedback signal FB is in an “L” state, the AND circuit 32a4 does not output the clock signal CLK. Therefore, the voltage of the voltage supply line 31 does not increase.

As illustrated in FIG. 6, the voltage dividing circuit 32b includes a resistor element 32b2 and a variable resistor element 32b4. The resistor element 32b2 is connected between the voltage supply line L_{VG} and a voltage dividing terminal 32b1. The variable resistor element 32b4 is connected in series between the voltage dividing terminal 32b1 and the voltage supply line L_{P}. The voltage supply line L_{P} is applied with the ground voltage V_{SS}. The variable resistor element 32b4 has a resistance value adjustable in accordance with an operating voltage control signal V_{CTR}L. Therefore, a magnitude of the voltage V_{OUT}′ of the voltage dividing terminal 32b1 is adjustable in accordance with the operating voltage control signal V_{CTRL}.

As illustrated in FIG. 6, the comparator 32c outputs the feedback signal FB. The feedback signal FB turns to the “L” state, for example, when the voltage V_{OUT}' of the voltage dividing terminal 32b1 is larger than the reference voltage V_{REF}. The feedback signal FB turns to the “H” state, for example, when the voltage V_{OUT}′ is smaller than the reference voltage V_{REF}.

### Configuration of Sequencer SQC

In accordance with command data Cmd stored in the command register CMR, the sequencer SQC (FIG. 4) outputs an internal control signal to the row decoders RD0, RD1, the sense amplifier modules SAM0, SAM1, and the voltage generation circuit VG. The sequencer SQC appropriately outputs status data Stt indicative of the state of the memory die MD to the status register STR.

The sequencer SQC generates a ready/busy signal and outputs it to a terminal RY//BY. In a period when the terminal RY//BY is in the “L” state (busy period), access to the memory die MD is basically inhibited. In a period when the terminal RY//BY is in the “H” state (ready period), access to the memory die MD is permitted. The terminal RY//BY is achieved by, for example, the pad electrode P described with reference to FIG. 2 and FIG. 3.

### Configuration of Address Register ADR

As illustrated in FIG. 4, the address register ADR is connected to the input/output control circuit I/O and stores address data Add input from the input/output control circuit I/O. For example, the address register ADR includes a plurality of 8-bit register strings. For example, when an internal operation, such as the read operation, the write operation, or the erase operation, is performed, the register string stores the address data Add corresponding to the internal operation in execution.

The address data Add, for example, includes the column address CA (FIG. 4) and the row address RA (FIG. 4). For example, the row address RA includes a block address to identify the memory block BLK (FIG. 5), a page address to identify the string unit SU and the word line WL, a plane address to identify the memory cell array MCA (plane), and a chip address to identify the memory die MD.

### Configuration of Command Register CMR

The command register CMR is connected to the input/output control circuit I/O and stores the command data Cmd input from the input/output control circuit I/O. For example, the command register CMR includes at least one set of an 8-bit register string. When the command data Cmd is stored in the command register CMR, the control signal is transmitted to the sequencer SQC.

### Configuration of Status Register STR

The status register STR is connected to the input/output control circuit I/O and stores the status data Stt output to the input/output control circuit I/O. For example, the status register STR includes a plurality of 8-bit register strings. For example, when the internal operation, such as the read operation, the write operation, or the erase operation, is performed, the register string stores the status data Stt regarding the internal operation in execution. The register string, for example, stores ready/busy information of the memory cell arrays MCA0, MCA1.

### Configuration of Input/Output Control Circuit I/O

The input/output control circuit I/O (FIG. 4) includes data signal input/output terminals DQn (n is a natural number from 0 to 7), data strobe signal input/output terminals DQS,/DQS, a shift register connected to the data signal input/output terminals DQn, a buffer circuit connected to the shift register, and power supply terminals VCCQ, VCC, VSS.

Each of the data signal input/output terminals DQn and the data strobe signal input/output terminals DQS,/DQS is achieved by, for example, the pad electrode P described with reference to FIG. 2 and FIG. 3. Data input via the data signal input/output terminals DQn are input to the cache memory CM, the address register ADR, or the command register CMR from the buffer circuit in response to the internal control signal from the logic circuit CTR. Data output via the data signal input/output terminals DQn are input to the buffer circuit from the cache memory CM or the status register STR in response to the internal control signal from the logic circuit CTR.

Signals input via the data strobe signal input/output terminals DQS,/DQS (for example, a data strobe signal and its complementary signal) are used at data input via the data signal input/output terminals DQn. The data input via the data signal input/output terminals DQn (n is a natural number from 0 to 7) are taken in the shift register in the input/output control circuit I/O at a timing of a voltage rise edge (switching of the input signal) of the data strobe signal input/output terminal DQS and a voltage fall edge (switching of the input signal) of the data strobe signal input/output terminal/DQS, and at a timing of a voltage fall edge (switching of the input signal) of the data strobe signal input/output terminal DQS and a voltage rise edge (switching of the input signal) of the data strobe signal input/output terminal/DQS.

The power supply terminals VCCQ, VCC, VSS are achieved by, for example, the pad electrodes P described with reference to FIG. 2 and FIG. 3. As illustrated in FIG. 8, the power supply terminal VCCQ and the power supply terminal VSS are connected to the shift register and the like included in the input/output control circuit I/O (FIG. 4). A capacitive element CP_{bp} is connected between the power supply terminal VCCQ and the power supply terminal VSS. The capacitive element CP_{bp} functions as what is called a bypass capacitor that stabilizes a power supply voltage, which is a voltage between the power supply terminal VCCQ and the power supply terminal VSS, even in high-speed operation.

### Configuration of Logic Circuit CTR

The logic circuit CTR (FIG. 4) includes a plurality of external control terminals/CE, CLE, ALE,/WE,/RE, RE and a logic circuit connected to these plurality of external control terminals/CE, CLE, ALE,/WE,/RE, RE. The logic circuit CTR receives an external control signal from the controller die CD via the external control terminals/CE, CLE, ALE,/WE,/RE, RE and outputs the internal control signal to the input/output control circuit I/O in response to this.

Note that, for example, each of the external control terminals/CE, CLE, ALE,/WE,/RE, RE is achieved by the pad electrode P described with reference to FIG. 2 and FIG. 3.

Structure of Memory Die MD

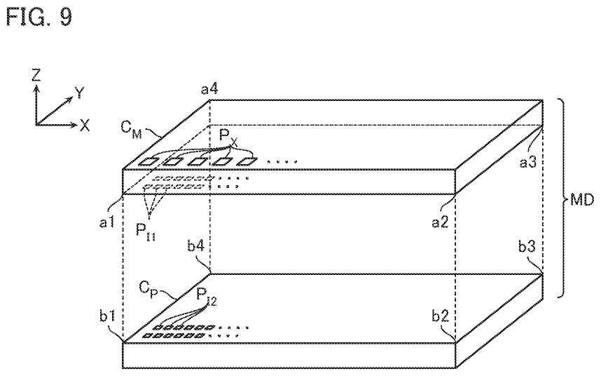

FIG. 9 is a schematic exploded perspective view illustrating an exemplary configuration of the semiconductor memory device according to the embodiment. As illustrated in FIG. 9, the memory die MD includes a chip C_{M} at the memory cell array side and a chip C_{P} at the peripheral circuit side.

On an upper surface of the chip C_{M}, a plurality of external pad electrodes P_{X} are disposed. On a lower surface of the chip CM, a plurality of first bonding electrodes P_{I1} are disposed. On an upper surface of the chip C_{P}, a plurality of second bonding electrodes P_{I2} are disposed. Hereinafter, regarding the chip C_{M}, a surface on which the plurality of first bonding electrodes P_{I1} are disposed is referred to as a front surface and a surface on which the plurality of external pad electrodes PX are disposed is referred to as a back surface. Additionally, regarding the chip C_{P}, a surface on which the plurality of second bonding electrodes P_{I2} are disposed is referred to as a front surface and a surface at a side opposite to the front surface is referred to as a back surface. In the example illustrated in the drawing, the surface of the chip C_{P} is disposed above the back surface of the chip C_{P} and the back surface of the chip C_{M} is disposed above the front surface of the chip C_{M}.

In the chip C_{M} and the chip C_{P}, the front surface of the chip CM is disposed to be opposed to the front surface of the chip C_{P}. The respective plurality of first bonding electrodes P_{I1} are disposed corresponding to the plurality of second bonding electrodes P_{I2} and are disposed at positions where the plurality of first bonding electrodes P_{I1} can be bonded to the plurality of second bonding electrodes P_{I2}. The first bonding electrode P_{I1} and the second bonding electrode P_{I2} function as bonding electrodes to bond the chip C_{M} and the chip C_{P} together to electrically conduct them. An external pad electrode P_{X} functions as the pad electrode P described with reference to FIG. 2 and FIG. 3.

In the example of FIG. 9, corner portions a1, a2, a3, a4 of the chip C_{M} correspond to corner portions b1, b2, b3, b4 of the chip C_{P}, respectively.

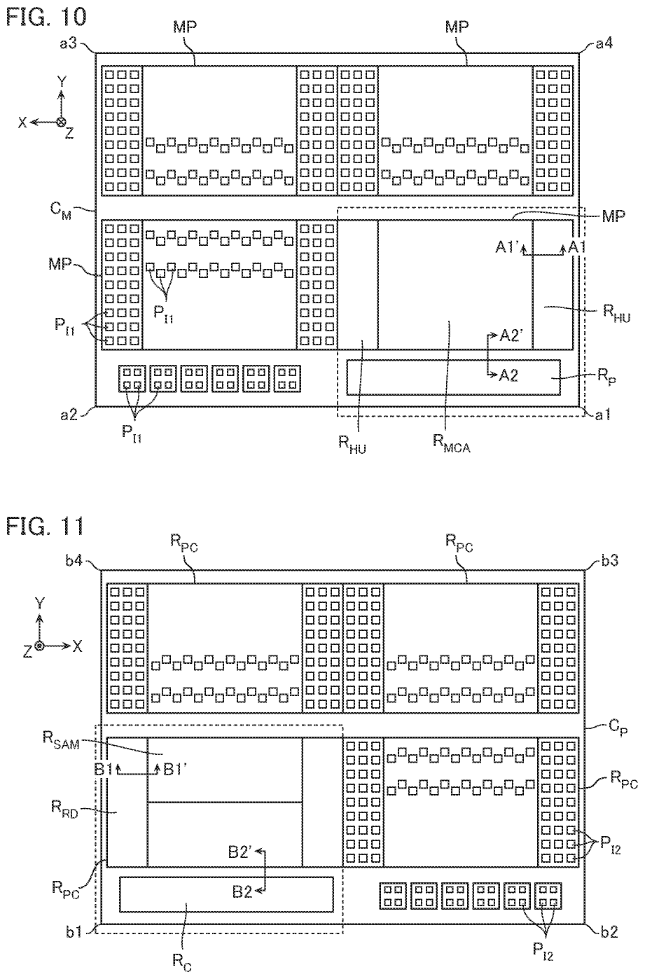

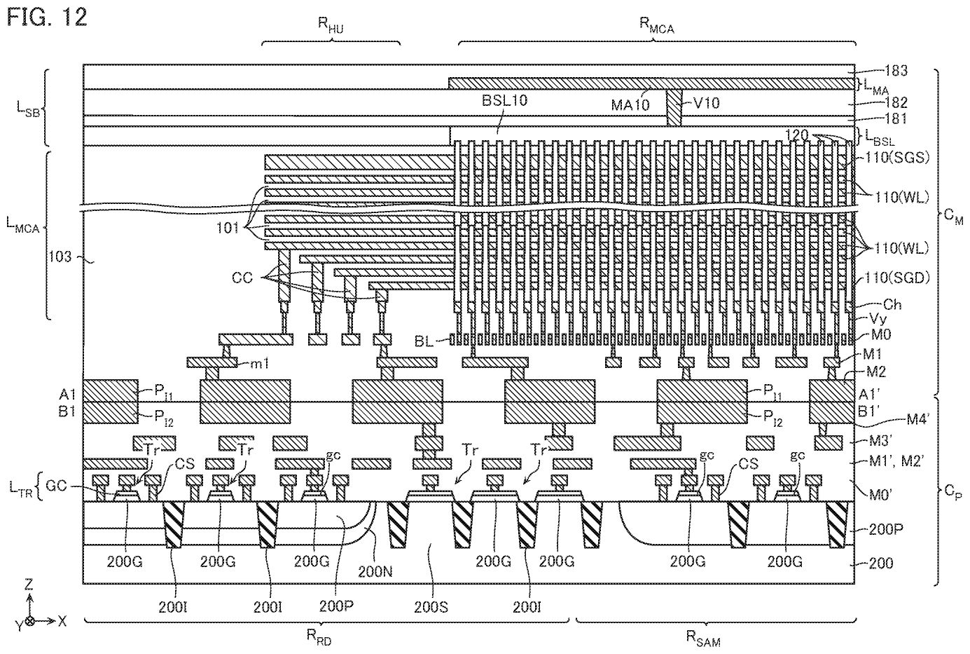

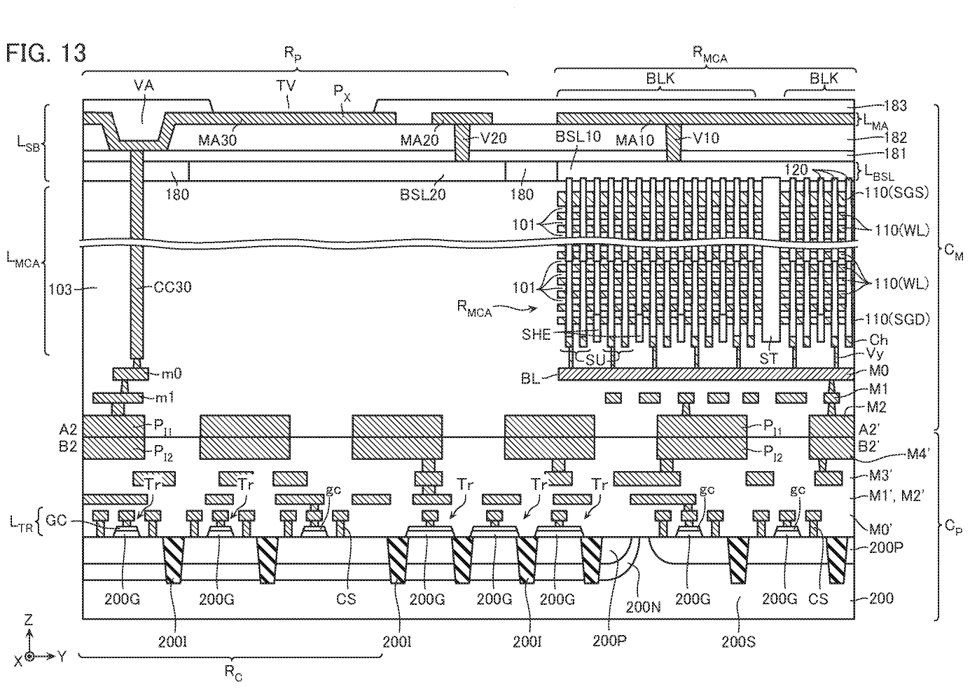

FIG. 10 is a schematic bottom view illustrating an exemplary configuration of the chip C_{M}. A lower right portion enclosed by a dotted line of FIG. 10 illustrates a structure inside the front surface of the chip C_{M} on which the plurality of first bonding electrodes P_{I1} are disposed. FIG. 11 is a schematic plan view illustrating an exemplary configuration of the chip C_{P}. A lower left portion enclosed by a dotted line of FIG. 11 illustrates a structure inside the front surface of the chip C_{P} on which the plurality of second bonding electrodes P_{I2} are disposed. FIG. 12 is a schematic cross-sectional view corresponding to a line A1-A1′ of FIG. 10 and a line B1-B1′ of FIG. 11. FIG. 13 is a schematic cross-sectional view corresponding to a line A2-A2′ of FIG. 10 and a line B2-B2′ of FIG. 11. FIG. 12 and FIG. 13 illustrate cross-sectional surfaces of the structures illustrated in FIG. 10 and FIG. 11 taken along each of the lines and viewed in directions of arrows.

### Structure of Chip C_{M}

For example, as illustrated in FIG. 10, the chip C_{M} includes four memory planes MP arranged in the X-direction and the Y-direction. The memory plane MP includes a memory cell array region R_{MCA} on which the above-described memory cell array MCA is disposed, and hook-up regions R_{HU} disposed at one end side and the other end side of the memory cell array region R_{MCA} in the X-direction. The chip C_{M} includes a peripheral region R_{P} disposed at one end side in the Y-direction with respect to the four memory planes MP.

For example, as illustrated in FIG. 12 and FIG. 13, the chip C_{M} includes a substrate layer L_{SB}, a memory cell array layer L_{MCA} disposed below the substrate layer L_{SB}, a plurality of wiring layers M0, M1, M2 disposed below the memory cell array layer L_{MCA}.

### Structure of Substrate Layer L_{SB} of Chip C_{M}

For example, as illustrated in FIG. 13, the substrate layer L_{SB} includes an insulating layer 183 disposed on the back surface of the chip C_{M}, a wiring layer L_{MA} disposed below the insulating layer 183, an insulating layer 182 disposed below the wiring layer L_{MA}, an insulating layer 181 disposed below the insulating layer 182, and a wiring layer L_{BSL} disposed below the insulating layer 181.

The insulating layer 183 is, for example, an insulating layer made of a passivation layer such as polyimide, silicon nitride (Si₃N₄), silicon oxide (SiO₂), or the like.

The wiring layer L_{MA} is, for example, a wiring layer containing a conductive material such as aluminum (Al). The wiring layer L_{MA} includes a conductive layer MA10 disposed in the memory cell array region R_{MCA}, and a conductive layer MA20 and a conductive layer MA30 disposed in the peripheral region R_{P}.

A part of the conductive layer MA30 is exposed to an outside of the memory die MD via an opening TV disposed in the insulating layer 183. This part functions as the external pad electrode P_{X}. A part of the conductive layer MA30 is in contact with an upper surface of the insulating layer 181 via an opening disposed in a part of the insulating layer 182. This part is electrically connected to the configuration in the chip C_{P} via a contact CC30 described later. Hereinafter, this part is referred to as an opening structure VA in some cases.

Although the illustration is omitted, a part of the conductive layer MA20 is also exposed to the outside of the memory die MD via the opening TV disposed in the insulating layer 183. This part functions as the external pad electrode P_{X}. Similarly to the conductive layer MA30, the conductive layer MA20 also includes the opening structure VA, and is electrically connected to the configuration in the chip C_{P} via the contact CC30 connected to this opening structure VA.

The insulating layer 182 is, for example, an insulating layer made of silicon nitride (Si₃N₄), silicon oxide (SiO₂), or the like. The insulating layer 181 is, for example, an insulating layer made of silicon oxide (SiO₂) or the like.

The wiring layer L_{BSL} is, for example, a wiring layer including a semiconductor layer of polycrystalline silicon (Si) or the like into which N-type impurities, such as phosphorus (P), or P-type impurities, such as boron (B), are implanted. The wiring layer L_{BSL} includes a conductive layer BSL10 disposed in the memory cell array region R_{MCA} and a conductive layer BSL20 disposed in the peripheral region R_{P}. Between the conductive layer BSL10 and the conductive layer BSL20, an insulating layer 180 of silicon oxide (SiO₂) or the like is disposed. The conductive layer BSL10 and the conductive layer BSL20 are electrically insulated from one another.

In the memory cell array region R_{MCA} of the substrate layer L_{SB}, a plurality of contacts V10 are disposed between the conductive layer MA10 and the conductive layer BSL10. The contact V10 extends in the Z-direction and has an upper end connected to the conductive layer MA10 and a lower end connected to the conductive layer BSL10. The contact V10 may include, for example, a stacked film of a barrier conductive film, such as titanium nitride (TiN), and a metal film, such as tungsten (W), or the like.

In the peripheral region R_{P} of the substrate layer L_{SB}, a plurality of contacts V20 are disposed between the conductive layer MA20 and the conductive layer BSL20. The contact V20 extends in the Z-direction and has an upper end connected to the conductive layer MA20 and a lower end connected to the conductive layer BSL20. The contact V20 may include, for example, a material similar to that of the contact V10.

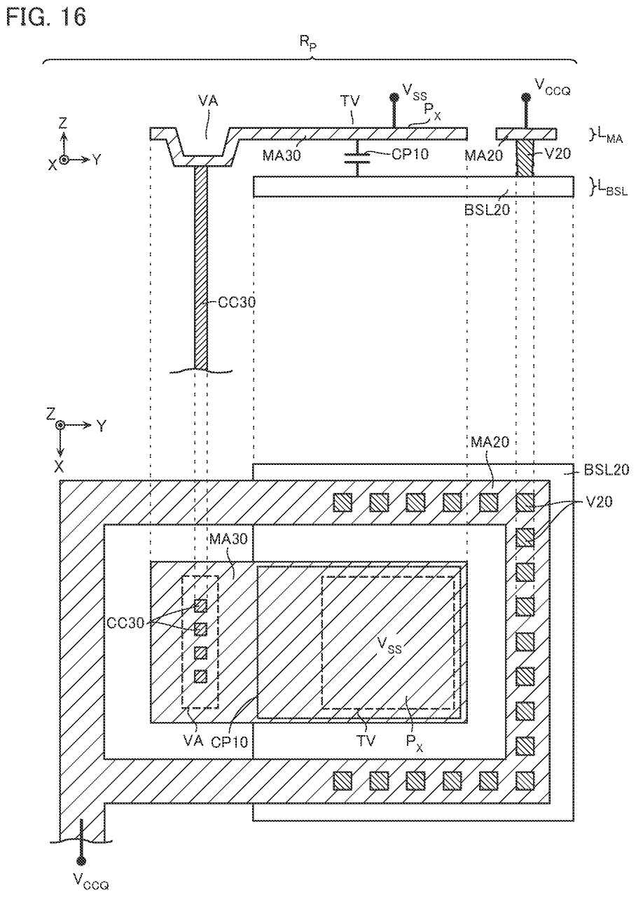

The conductive layer MA20, the conductive layer MA30, and the conductive layer BSL20 disposed in the peripheral region R_{P} of the substrate layer L_{SB} constitute a capacitive element CP10 (FIG. 16) described later. The capacitive element CP10 functions as, for example, the capacitive element CP_{bp} described with reference to FIG. 8. The conductive layer MA20, the conductive layer MA30, the conductive layer BSL20, and the capacitive element CP10 is described later.

### Structure of Memory Cell Array Layer L_{MCA} of Chip C_{M} in Memory Cell Array Region R_{MCA}

For example, as illustrated in FIG. 13, a plurality of memory blocks BLK arranged in the Y-direction are disposed in the memory cell array region R_{MCA}. The memory block BLK includes a plurality of string units SU arranged in the Y-direction. An inter-block insulating layer ST of silicon oxide (SiO₂) or the like is disposed between two memory blocks BLK mutually adjacent in the Y-direction. An inter-string unit insulating layer SHE of silicon oxide (SiO₂) or the like is disposed between two string units SU mutually adjacent in the Y-direction.

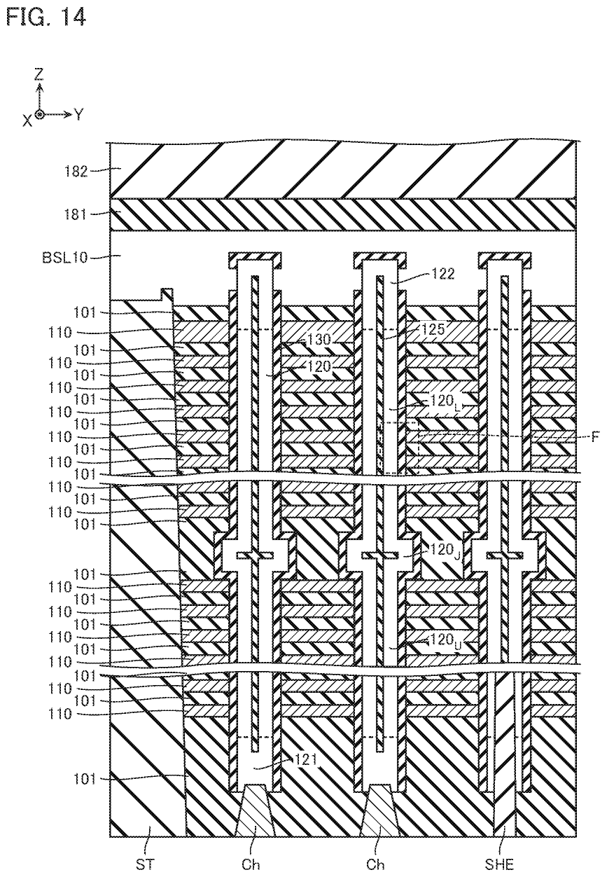

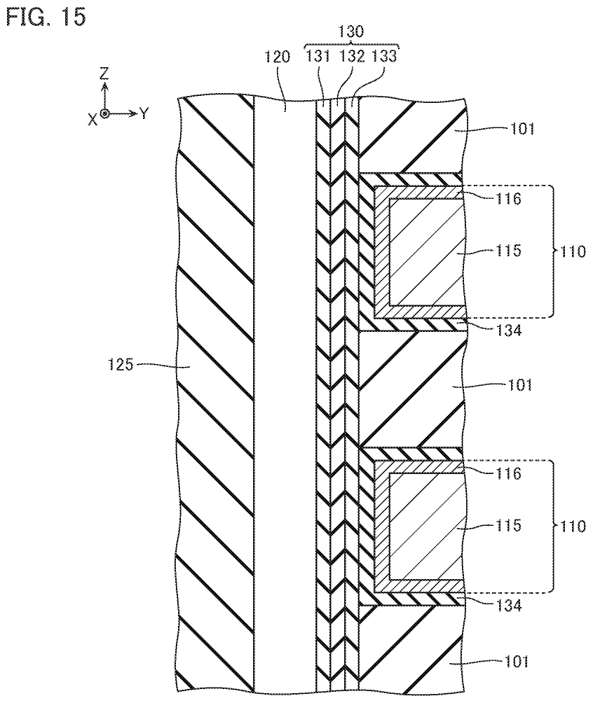

FIG. 14 is a schematic enlarged cross-sectional view of the memory cell array region R_{MCA}. FIG. 15 is a schematic enlarged view of a part indicated by F in FIG. 14. While FIG. 15 illustrates a Y-Z cross-sectional surface, the structure similar to that in FIG. 15 is also observed when a cross-sectional surface other than the Y-Z cross-sectional surface (for example, an X-Z cross-sectional surface) along a central axis of a semiconductor column 120 is observed.

For example, as illustrated in FIG. 14, the memory block BLK includes a plurality of conductive layers 110 arranged in the Z-direction, a plurality of semiconductor columns 120 extending in the Z-direction, and a plurality of gate insulating films 130 each disposed between the plurality of conductive layers 110 and the plurality of semiconductor columns 120.

The conductive layer 110 is an approximately plate-shaped conductive layer extending in the X-direction. As illustrated in FIG. 15, the conductive layer 110 may include a stacked film including a barrier conductive film 116, such as titanium nitride (TiN), and a metal film 115, such as tungsten (W), or the like. An insulating metal oxide film 134, such as alumina (AlO), may be disposed at a position covering an outer periphery of the barrier conductive film 116. For example, the conductive layer 110 may contain polycrystalline silicon containing impurities, such as phosphorus (P) or boron (B), or the like. Between the plurality of conductive layers 110 arranged in the Z-direction, insulating layers 101 of silicon oxide (SiO₂) or the like are disposed.

As illustrated in FIG. 14, the above-described conductive layer BSL10 is disposed above the conductive layer 110. The conductive layer BSL10 is connected to an upper end of the semiconductor column 120. Between the conductive layer 110 and the conductive layer BSL10, the insulating layer 101 of silicon oxide (SiO₂) or the like is disposed. The conductive layer BSL10 functions as the source line SL (FIG. 5). The source line SL is, for example, disposed in common in all the memory blocks BLK included in the memory cell array region R_{MCA} (FIG. 12 and FIG. 13).

Among the plurality of conductive layers 110, one or a plurality of conductive layers 110 positioned at an uppermost layer function as the source-side select gate line SGS (FIG. 5) and gate electrodes of a plurality of source-side select transistors STS connected thereto. These plurality of conductive layers 110 are electrically independent in every memory block BLK.

The plurality of conductive layers 110 positioned below these conductive layers 110 function as the word lines WL (FIG. 5) and gate electrodes of the plurality of memory cells MC (FIG. 5) connected thereto. These plurality of conductive layers 110 are each electrically independent in every memory block BLK.

One or a plurality of conductive layers 110 positioned below these conductive layers 110 function as the drain-side select gate line SGD and gate electrodes of the plurality of drain-side select transistors STD (FIG. 5) connected thereto. These plurality of conductive layers 110 have widths in the Y-direction smaller than those of the other conductive layers 110. The inter-string unit insulating layer SHE is disposed between two conductive layers 110 mutually adjacent in the Y-direction. These plurality of conductive layers 110 are each electrically independent in every string unit SU.

For example, as illustrated in FIG. 12 and FIG. 13, the semiconductor columns 120 are arranged in the X-direction and the Y-direction in a predetermined pattern. The semiconductor columns 120 function as the channel regions of the plurality of memory cells MC and the select transistors (STD, STS) included in one memory string MS (FIG. 5). The semiconductor column 120 is, for example, a semiconductor layer of polycrystalline silicon (Si) or the like. A center part of the semiconductor column 120 is provided with an insulating layer 125 (FIG. 14) of silicon oxide or the like.

As illustrated in FIG. 14, the semiconductor column 120 includes a semiconductor region 120_{L} and a semiconductor region 120_{U} disposed below the semiconductor region 120_{L}. The semiconductor column 120 includes a semiconductor region 120_{J} connected to a lower end of the semiconductor region 120_{L} and an upper end of the semiconductor region 120_{U}, an impurity region 122 connected to an upper end of the semiconductor region 120_{L}, and an impurity region 121 connected to a lower end of the semiconductor region 120_{U}.

The semiconductor region 120_{L} and the semiconductor region 120_{U} are substantially cylindrically-shaped regions extending in the Z-direction. Outer peripheral surfaces of the semiconductor region 120_{L} and the semiconductor region 120_{U} are each surrounded by the plurality of conductive layers 110 included in the memory cell array layer L_{MCA} and opposed to these plurality of conductive layers 110.

The impurity region 121 contains, for example, N-type impurities, such as phosphorus (P). In the example in FIG. 14, a boundary line between a lower end portion of the semiconductor region 120_{U} and an upper end portion of the impurity region 121 is indicated by a dashed line. The impurity region 121 is connected to the bit line BL via a contact Ch and a contact Vy (FIG. 12 and FIG. 13).

The impurity region 122 contains, for example, N-type impurities, such as phosphorus (P), and P-type impurities, such as boron (B). In the example in FIG. 14, a boundary line between an upper end portion of the semiconductor region 120_{L} and a lower end portion of the impurity region 122 is indicated by a dashed line. The impurity region 122 is connected to the conductive layer BSL10.

As described above, the conductive layer BSL10 is connected to the conductive layer MA10 via the plurality of contacts V10. The conductive layer MA10 contains, for example, a conductive material such as aluminum (Al) and has low resistance. The conductive layer MA10 functions as an auxiliary wiring for the conductive layer BSL10 that functions as the source line SL. The conductive layer BSL10 may be disposed over a region overlapping the plurality of semiconductor columns 120 when viewed in the Z-direction.

The gate insulating film 130 has a cylindrical shape covering an outer peripheral surface of the semiconductor column 120. For example, as illustrated in FIG. 15, the gate insulating film 130 includes a tunnel insulating film 131, an electric charge accumulating film 132, and a block insulating film 133, which are stacked between the semiconductor column 120 and the conductive layers 110. The tunnel insulating film 131 and the block insulating film 133 are, for example, insulating films of silicon oxide (SiO₂) or the like. The electric charge accumulating film 132 is, for example, a film of silicon nitride (Si₃N₄) or the like that can accumulate electric charge. The tunnel insulating film 131, the electric charge accumulating film 132, and the block insulating film 133 have substantially cylindrical shapes and extend in the Z-direction along the outer peripheral surface of the semiconductor column 120.

FIG. 15 illustrates an example in which the gate insulating film 130 includes the electric charge accumulating film 132 of silicon nitride or the like. However, the gate insulating film 130 may include, for example, a floating gate of polycrystalline silicon or the like containing N-type or P-type impurities.

### Structure of Memory Cell Array Layer L_{MCA} of Chip C_{M} in Hook-Up Region R_{HU}

As illustrated in FIG. 12, a plurality of contacts CC are disposed in a hook-up region R_{HU}. These plurality of contacts CC extend in the Z-direction and each of them has an upper end connected to the conductive layer 110. These plurality of contacts CC are connected to the configuration in the chip C_{P} via wirings m0, m1 in the wiring layers M0, M1 and the first bonding electrode P_{I1} in the wiring layer M2. The contact CC may include, for example, a stacked film of a barrier conductive film, such as titanium nitride (TiN), and a metal film, such as tungsten (W), or the like.

### Structure of Memory Cell Array Layer L_{MCA} of Chip C_{M} in Peripheral Region R_{P}

For example, as illustrated in FIG. 13, the contact CC30 is disposed in the peripheral region R_{P}. A part of the contact CC30 has an upper end connected to a lower surface of the conductive layer MA30 and a lower end connected to the wiring m0 or the like described later.

### Structure of Wiring Layers M0, M1, M2 of Chip C_{M}

For example, as illustrated in FIG. 12 and FIG. 13, a plurality of wirings included in the wiring layers M0, M1, M2 are, for example, electrically connected to at least one of the configuration in the memory cell array layer L_{MCA} and the configuration in the chip C_{P}.

The wiring layer M0 includes a plurality of wirings m0. These plurality of wirings m0 may include, for example, a stacked film of a barrier conductive film, such as titanium nitride (TiN), and a metal film, such as copper (Cu), or the like. Note that a part of the plurality of wirings m0 function as the bit lines BL (FIG. 5). For example, as illustrated in FIG. 12 and FIG. 13, the bit lines BL are arranged in the X-direction and extend in the Y-direction. These plurality of bit lines BL are each connected to one semiconductor column 120 included in each of the string units SU.

For example, as illustrated in FIG. 12 and FIG. 13, the wiring layer M1 includes a plurality of wirings m1. These plurality of wirings m1 may include, for example, a stacked film of a barrier conductive film, such as titanium nitride (TiN), and a metal film, such as copper (Cu), or the like.

The wiring layer M2 includes the plurality of first bonding electrodes P_{I1}. These plurality of first bonding electrodes P_{I1} may include, for example, a stacked film of a barrier conductive film, such as titanium nitride (TiN), and a metal film, such as copper (Cu), or the like.

### Structure of Chip C_{P}

For example, as illustrated in FIG. 11, the chip C_{P} includes four peripheral circuit regions R_{PC} arranged in the X-direction and the Y-direction corresponding to the memory planes MP. The peripheral circuit region R_{PC} includes a sense amplifier module region R_{SAM} disposed in a part of a region opposed to the memory cell array region R_{MCA}, and row decoder regions R_{RD} disposed in regions opposed to the hook-up regions R_{HU}. The chip C_{P} includes a circuit region R_{C} disposed in a region opposed to the peripheral region R_{P}.

For example, as illustrated in FIG. 12 and FIG. 13, the chip C_{P} includes a semiconductor substrate 200, a transistor layer L_{TR} disposed above the semiconductor substrate 200, and a plurality of wiring layers M0′, M1′, M2′, M3′, M4′ disposed above the transistor layer L_{TR}.

### Structure of Semiconductor Substrate 200 in Chip C_{P}

The semiconductor substrate 200 is, for example, a semiconductor substrate made of P-type silicon (Si) containing P-type impurities, such as boron (B). For example, as illustrated in FIG. 12 and FIG. 13, on a surface of the semiconductor substrate 200, N-type well regions 200N containing N-type impurities, such as phosphorus (P), P-type well regions 200P containing P-type impurities, such as boron (B), a semiconductor substrate region 200S in which the N-type well region 200N or the P-type well region 200P is not disposed, and insulating regions 200I are disposed. The respective N-type well regions 200N, P-type well regions 200P, and the semiconductor substrate region 200S function as parts of a plurality of transistors Tr, a plurality of capacitors, and the like constituting the peripheral circuit PC.

### Structure of Transistor Layer L_{TR} in Chip C_{P}

For example, as illustrated in FIG. 12 and FIG. 13, a wiring layer GC is disposed on an upper surface of the semiconductor substrate 200 via an insulating layer 200G. The wiring layer GC includes a plurality of electrodes gc opposed to the surface of the semiconductor substrate 200. Each region of the semiconductor substrate 200 and each of the plurality of electrodes gc included in the wiring layer GC are connected to a contact CS.

The respective N-type well regions 200N, P-type well regions 200P, and semiconductor substrate region 200S of the semiconductor substrate 200 function as channel regions of the plurality of transistors Tr, one electrodes of the plurality of capacitors, and the like constituting the peripheral circuit PC.

The respective plurality of electrodes gc included in the wiring layer GC function as gate electrodes of the plurality of transistors Tr, the other electrodes of the plurality of capacitors, and the like constituting the peripheral circuit PC.

The contact CS extends in the Z-direction and has a lower end connected to the semiconductor substrate 200 or the upper surface of the electrode gc. An impurity region containing N-type impurities or P-type impurities is disposed in a connection part of the contact CS and the semiconductor substrate 200. The contact CS may include, for example, a stacked film of a barrier conductive film, such as titanium nitride (TiN), and a metal film, such as tungsten (W), or the like.

### Structure of Wiring Layer M0′, M1′, M2′, M3′, M4′ in Chip C_{P}

The wiring layer M0′ is disposed above the transistor layer L_{TR}. The wiring layer M0′ is, for example, a wiring layer containing a conductive material, such as tungsten (W). The wiring layer M1′ is disposed above the wiring layer M0′. The wiring layer M1′ is, for example, a wiring layer containing a conductive material, such as copper (Cu). The wiring layer M2′, which is omitted in FIG. 12 and FIG. 13, is disposed above the wiring layer M1′. The wiring layer M2′ is, for example, a wiring layer containing a conductive material, such as copper (Cu). The wiring layer M3′ is, for example, a wiring layer containing a conductive material, such as copper (Cu) or aluminum (Al). The wiring layer M4′ is, for example, a wiring layer containing a conductive material, such as copper (Cu), and includes the plurality of second bonding electrodes P_{I2}.

### Capacitive Element CP10

Next, the capacitive element CP10 is described with reference to FIG. 16. FIG. 16 is a partially enlarged schematic diagram of the structure of the peripheral region R_{P} of the substrate layer L_{SB} in the chip C_{M}. An upper portion of FIG. 16 is a schematic cross-sectional view illustrating an exemplary configuration of the capacitive element CP10, and a lower portion of FIG. 16 is a schematic plan view of a portion corresponding to the upper portion of FIG. 16.

FIG. 16 illustrates the conductive layer MA30 and the conductive layer MA20 disposed in the wiring layer L_{MA}, the conductive layer BSL20 disposed in the wiring layer L_{BSL}, the contacts V20 connected to the conductive layer BSL20 and the conductive layer MA30, and the contacts CC30 connected to the conductive layer MA30.

As illustrated in the lower portion of FIG. 16, the capacitive element CP10 is disposed in a region where the conductive layer MA30 and the conductive layer BSL20 overlap when viewed in the Z-direction. That is, a portion of the conductive layer MA30 opposed to the conductive layer BSL20 functions as an electrode at one side of the capacitive element CP10, and a portion of the conductive layer BSL20 opposed to the conductive layer MA30 functions as an electrode at the other side of the capacitive element CP10.

The conductive layer MA30 includes a portion functioning as the external pad electrode P_{X} (bonding pad). The portion functioning as the external pad electrode P_{X} of the conductive layer MA30 also functions as the electrode at one side of the capacitive element CP10. The ground voltage V_{SS} is applied to the conductive layer MA30.

The conductive layer MA20 includes a portion surrounding four sides of the conductive layer MA30 on both sides in the X-direction and the Y-direction. The conductive layer MA20 includes a portion overlapping the conductive layer BSL20 when viewed in the Z-direction. The plurality of contacts V20 are disposed at a portion where the conductive layer MA20 and the conductive layer BSL20 overlap when viewed in the Z-direction. A power supply voltage V_{CCQ} is applied to the conductive layer BSL20 via the contacts V20 and the conductive layer MA20. While the above description has shown an example in which the ground voltage V_{SS} is applied to the conductive layer MA30 and the power supply voltage V_{CCQ} larger than the ground voltage V_{SS} is applied to the conductive layer BSL20, the power supply voltage V_{CCQ} may be applied to the conductive layer MA30 and the ground voltage V_{SS} may be applied to the conductive layer BSL20.

### Effects

As an interface speed of the semiconductor memory device increases, fluctuations in voltages of the power supply terminals VCCQ, VSS are increasing. In such a case, it has been difficult to stably supply electric power to each configuration of the semiconductor memory device, and the semiconductor memory device cannot be operated stably in some cases. To reduce this, for example, increasing capacitance of the bypass capacitor (capacitive element CP_{bp} (FIG. 8)) connected to the power supply terminals VCCQ, VSS may be considered.

To form the capacitive element, for example, it is also possible to use the wiring in the wiring layer or the channel region and the gate electrode of the transistor in the transistor layer L_{TR}. However, when the capacitance of the capacitive element with such a configuration is attempted to be increased, it becomes necessary to reduce an area of the wiring in the wiring layer or an area of the transistor in the transistor layer L_{TR}.

Here, in this embodiment, the wiring layer L_{MA} is provided with the conductive layer MA10 that functions as an auxiliary wiring for the source line SL in the memory cell array region R_{MCA}, and provided with the conductive layer MA30 that partially functions as the external pad electrode P_{X} in the peripheral region R_{P} (FIG. 13). On the other hand, while the wiring layer L_{BSL} is provided with the conductive layer BSL10 that functions as the source line SL in the memory cell array region R_{MCA}, no conductive layer as the source line SL is disposed in the peripheral region R_{P}.

Therefore, in the wiring layer L_{BSL} in the peripheral region R_{P}, the conductive layer BSL20 with a relatively large area can be arranged at a position opposed to the conductive layer MA30. With such conductive layer MA30 and conductive layer BSL20, it is possible to configure the capacitive element CP10 with relatively large capacitance that is electrically connected to the external pad electrode P_{X}.

When such a capacitive element CP10 is used as the bypass capacitor, it is not necessary to decrease the area of the wiring or the transistor. Thus, even when high integration of the semiconductor memory device proceeds, the interface speed of the semiconductor memory device can be increased without destabilizing an operation of the semiconductor memory device.

The conductive layer MA20 can be formed collectively when the conductive layer MA30 functioning as the external pad electrode P_{X} is formed. The conductive layer BSL20 can be formed collectively when the conductive layer BSL10 functioning as the source line is formed. The contact V20 connected to the conductive layer BSL20 can be formed collectively when the contact V10 connected to the conductive layer MA10 is formed. The contact CC30 connected to the conductive layer MA30 can be formed collectively when another contact CC or the like is formed. Therefore, the semiconductor memory device according to the embodiment can be achieved without increasing a manufacturing cost.

### Modification 1 of First Embodiment

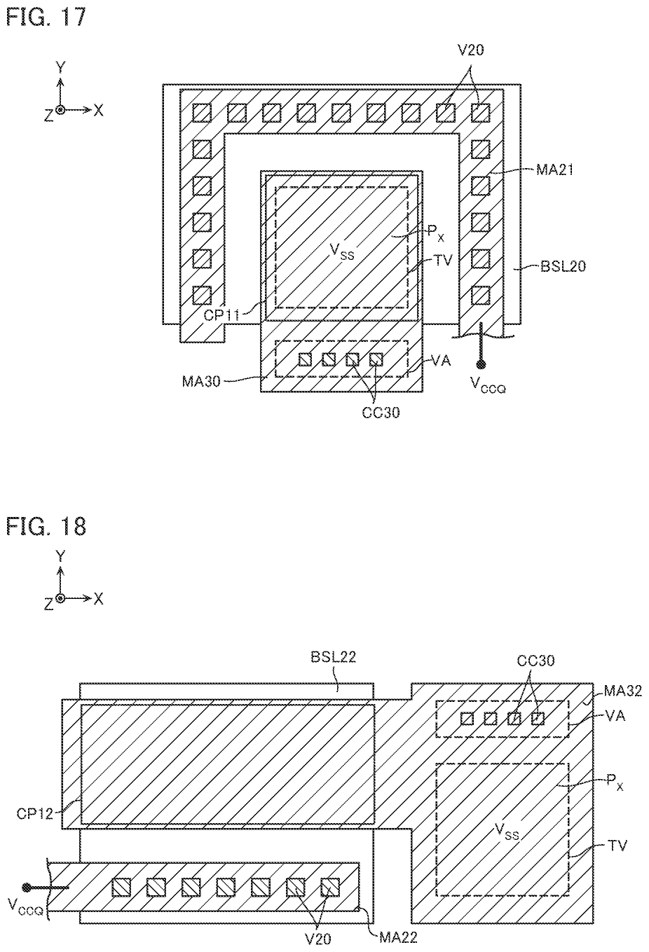

Next, with reference to FIG. 17, Modification 1 of the semiconductor memory device according to the first embodiment is described. FIG. 17 is a schematic plan view illustrating a configuration of a part of the semiconductor memory device according to the modification.

### Capacitive Element CP11

The semiconductor memory device according to the modification is basically configured similarly to the semiconductor memory device according to the first embodiment. However, for example, as illustrated in FIG. 17, the semiconductor memory device according to the modification includes a capacitive element CP11 instead of the capacitive element CP10. The capacitive element CP11 is basically configured similarly to the capacitive element CP10. However, the capacitive element CP11 includes a conductive layer MA21 instead of the conductive layer MA20.

The conductive layer MA21 is basically configured similarly to the conductive layer MA20. However, when viewed in the Z-direction, the conductive layer MA21 includes a portion surrounding three sides of the conductive layer MA30 on both sides in the X-direction and one side in the Y-direction. The plurality of contacts V20 are disposed at a portion where the conductive layer MA21 and the conductive layer BSL20 overlap when viewed in the Z-direction. The power supply voltage V_{CCQ} is applied to the conductive layer BSL20 via the contacts V20 and the conductive layer MA21.

While the above description has shown an example in which the ground voltage V_{SS} is applied to the conductive layer MA30 and the power supply voltage V_{CCQ} larger than the ground voltage V_{SS} is applied to the conductive layer BSL20, the power supply voltage V_{CCQ} may be applied to the conductive layer MA30 and the ground voltage V_{SS} may be applied to the conductive layer BSL20.

### Modification 2 of First Embodiment

Next, with reference to FIG. 18, Modification 2 of the semiconductor memory device according to the first embodiment is described. FIG. 18 is a schematic plan view illustrating a configuration of a part of the semiconductor memory device according to the modification.

### Capacitive Element CP12

The semiconductor memory device according to the modification is basically configured similarly to the semiconductor memory device according to the first embodiment. However, for example, as illustrated in FIG. 18, the semiconductor memory device according to the modification includes a capacitive element CP12 instead of the capacitive element CP10. The capacitive element CP12 is basically configured similarly to the capacitive element CP10. However, the capacitive element CP12 includes a conductive layer MA22, a conductive layer MA32, and a conductive layer BSL22 instead of the conductive layer MA20, the conductive layer MA30, and the conductive layer BSL20.

The conductive layer MA32 is basically configured similarly to the conductive layer MA30. However, in the conductive layer MA32, a portion functioning as the external pad electrode P_{X} is different from a portion functioning as an electrode at one side of the capacitive element CP12. In the illustrated example, the portion functioning as the electrode at one side of the capacitive element CP12 of the conductive layer MA32 is disposed at a negative side in the X-direction with respect to the portion functioning as the external pad electrode P_{X} and extends in the X-direction. The opening structure VA is disposed at a positive side in the Y-direction with respect to the portion functioning as the external pad electrode P_{X}.

The conductive layer MA22 is basically configured similarly to the conductive layer MA20. However, the conductive layer MA22 extends in one direction, for example, in the X-direction, and includes a portion overlapping the conductive layer BSL22 when viewed in the Z-direction. The plurality of contacts V20 are disposed at a portion where the conductive layer MA22 and the conductive layer BSL22 overlap when viewed in the Z-direction. The power supply voltage V_{CCQ} is applied to the conductive layer BSL22 via the contacts V20 and the conductive layer MA22.

While the above description has shown an example in which the ground voltage V_{SS} is applied to the conductive layer MA32 and the power supply voltage V_{CCQ} larger than the ground voltage V_{SS} is applied to the conductive layer BSL22, the power supply voltage V_{CCQ} may be applied to the conductive layer MA32 and the ground voltage V_{SS} may be applied to the conductive layer BSL22.

### Modification 3 of First Embodiment

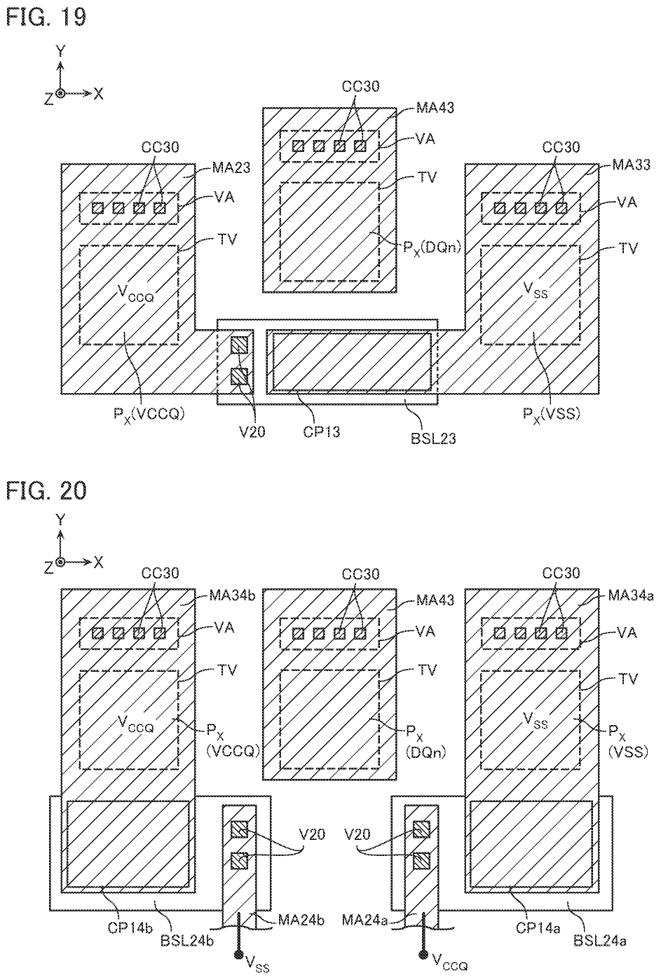

Next, with reference to FIG. 19, Modification 3 of the semiconductor memory device according to the first embodiment is described. FIG. 19 is a schematic plan view illustrating a configuration of a part of the semiconductor memory device according to the modification.

### Capacitive Element CP13

The semiconductor memory device according to the modification is basically configured similarly to the semiconductor memory device according to the first embodiment. However, for example, as illustrated in FIG. 19, the semiconductor memory device according to the modification includes a capacitive element CP13 instead of the capacitive element CP10. In FIG. 19, a conductive layer MA43 is illustrated.

The conductive layer MA43 includes a portion functioning as the external pad electrode P_{X} (DQn). This portion may be disposed, for example, between the external pad electrode P_{X} (VCCQ) and the external pad electrode P_{X} (VSS). The conductive layer MA43 does not include a portion overlapping the conductive layer BSL23 when viewed in the Z-direction. The conductive layer MA43 includes the opening structure VA connected to a plurality of contacts CC30.

The capacitive element CP13 is basically configured similarly to the capacitive element CP10. However, the capacitive element CP13 includes a conductive layer MA23, a conductive layer MA33, and a conductive layer BSL23 instead of the conductive layer MA20, the conductive layer MA30, and the conductive layer BSL20.

The conductive layer MA33 is basically configured similarly to the conductive layer MA30. However, in the conductive layer MA33, a portion functioning as the external pad electrode P_{X} is different from a portion functioning as an electrode at one side of the capacitive element CP13. In the illustrated example, the portion functioning as the electrode at one side of the capacitive element CP13 of the conductive layer MA33 is disposed at a negative side in the Y-direction with respect to the conductive layer MA43 and extends in the X-direction. The opening structure VA is disposed at the positive side in the Y-direction with respect to the portion functioning as the external pad electrode P_{X}.

The conductive layer MA23 is basically configured similarly to the conductive layer MA20. However, the conductive layer MA23 does not include the portion surrounding four sides of the conductive layer MA30 on both sides in the X-direction and the Y-direction.

While the above description has shown an example in which the ground voltage V_{SS} is applied to the conductive layer MA33 and the power supply voltage V_{CCQ} larger than the ground voltage V_{SS} is applied to the conductive layer BSL23, the power supply voltage V_{CCQ} may be applied to the conductive layer MA33 and the ground voltage V_{SS} may be applied to the conductive layer BSL23.

### Modification 4 of First Embodiment

Next, with reference to FIG. 20, Modification 4 of the semiconductor memory device according to the first embodiment is described. FIG. 20 is a schematic plan view illustrating a configuration of a part of the semiconductor memory device according to the modification.

### Capacitive Element CP14a, Capacitive Element CP14b

The semiconductor memory device according to the modification is basically configured similarly to the semiconductor memory device according to the first embodiment. However, for example, as illustrated in FIG. 20, the semiconductor memory device according to the modification includes a capacitive element CP14a and a capacitive element CP14b instead of the capacitive element CP10.

The capacitive element CP14a includes, for example, a conductive layer MA24a, a conductive layer MA34a, and a conductive layer BSL24a.

The conductive layer MA34a is basically configured similarly to the conductive layer MA30. However, in the conductive layer MA34a, a portion functioning as the external pad electrode P_{X} is different from a portion functioning as an electrode at one side of the capacitive element CP14a. In the illustrated example, the portion functioning as the electrode at one side of the capacitive element CP14a of the conductive layer MA34a is disposed at the negative side in the Y-direction with respect to the portion functioning as the external pad electrode P_{X}. The opening structure VA is disposed at the positive side in the Y-direction with respect to the portion functioning as the external pad electrode P_{X}.

The conductive layer MA24a is basically configured similarly to the conductive layer MA20. However, the conductive layer MA24a includes a portion overlapping the conductive layer BSL24a when viewed in the Z-direction.

The capacitive element CP14b includes, for example, a conductive layer MA24b, a conductive layer MA34b, and a conductive layer BSL24b. The conductive layer MA24b, the conductive layer MA34b, and the conductive layer BSL24b are basically configured similarly to the conductive layer MA24a, the conductive layer MA34a, and the conductive layer BSL24a.

However, the power supply voltage V_{CCQ} is applied to the conductive layer MA34b via the external pad electrode P_{X} (VCCQ). The ground voltage V_{SS} is applied to the conductive layer BSL24b via the conductive layer MA24b and the contacts V20.

The conductive layer MA24a may be continuously formed with the conductive layer MA34b. Similarly, the conductive layer MA24b may be continuously formed with the conductive layer MA34a.

### Second Embodiment

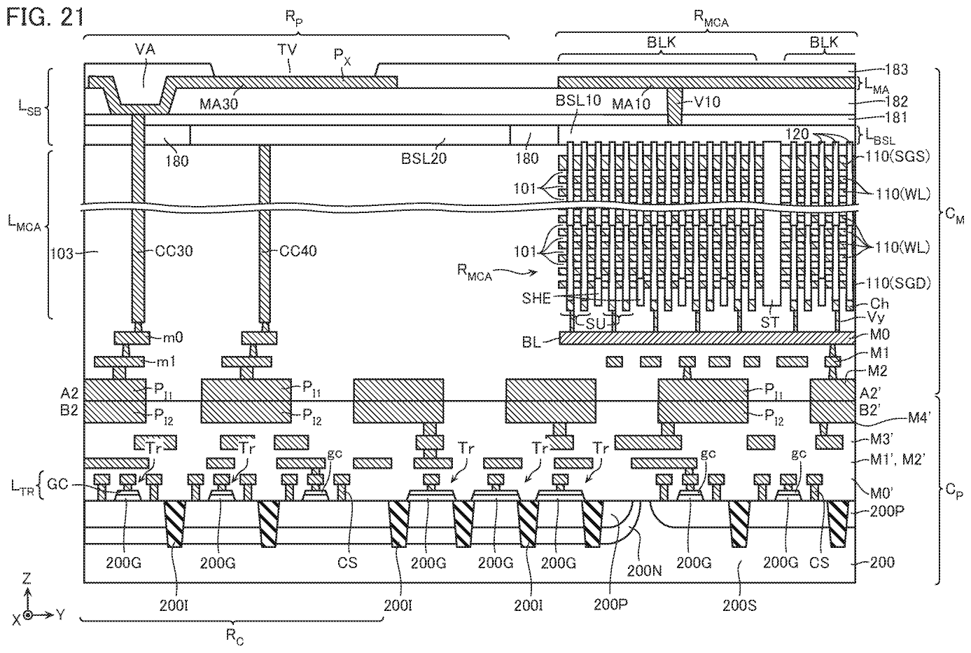

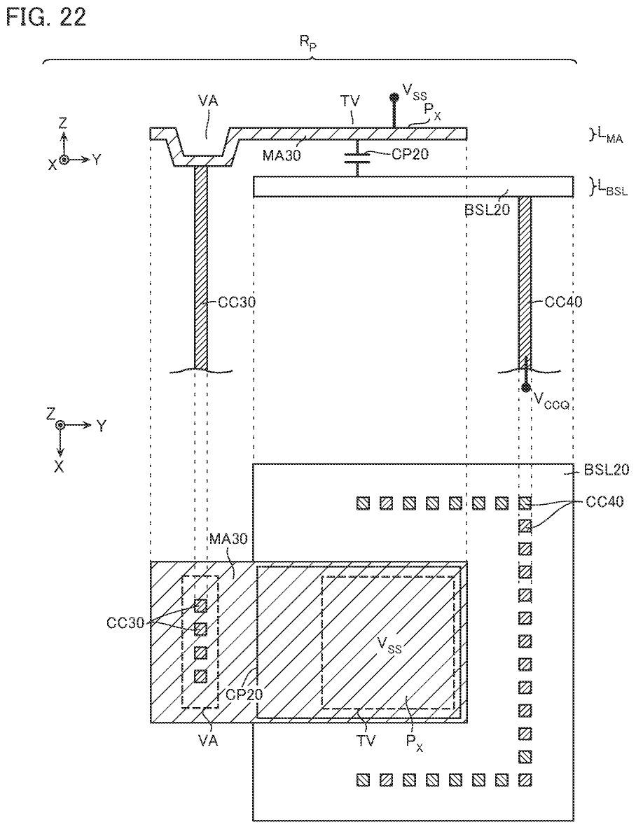

Next, with reference to FIG. 21 and FIG. 22, a semiconductor memory device according to the second embodiment is described. FIG. 21 is a schematic cross-sectional view illustrating a configuration of a part of the semiconductor memory device according to the second embodiment, and illustrates a portion corresponding to FIG. 13. An upper portion of FIG. 22 is a schematic cross-sectional view illustrating an exemplary configuration of a capacitive element CP20 according to the second embodiment, and a lower portion of FIG. 22 is a schematic plan view of a portion corresponding to the upper portion of FIG. 22. In the following description, descriptions of the configuration similar to those in the first embodiment may be omitted.

The semiconductor memory device according to the embodiment is basically configured similarly to the semiconductor memory device according to the first embodiment. However, the semiconductor memory device according to the second embodiment includes the capacitive element CP20 instead of the capacitive element CP10.

### Capacitive Element CP20

The capacitive element CP20 is basically configured similarly to the capacitive element CP10. However, as described with reference to FIG. 13 and FIG. 16, the capacitive element CP10 is provided with the contact V20 and the conductive layer MA20 connected to the conductive layer BSL20 from above. Meanwhile, as illustrated in FIG. 21 and FIG. 22, the capacitive element CP20 is provided with a contact CC40 connected to the conductive layer BSL20 from below.

A plurality of contacts CC40 may be disposed at a portion overlapping the conductive layer BSL20 when viewed in the Z-direction. For example, the plurality of contacts CC40 may be disposed at positions overlapping the external pad electrode P_{X} or may be disposed at positions that do not overlap the external pad electrode P_{X} when viewed in the Z-direction.

While the above description has shown an example in which the ground voltage V_{SS} is applied to the conductive layer MA30 and the power supply voltage V_{CCQ} larger than the ground voltage V_{SS} is applied to the conductive layer BSL20, the power supply voltage V_{CCQ} may be applied to the conductive layer MA30 and the ground voltage V_{SS} may be applied to the conductive layer BSL20.

### Third Embodiment

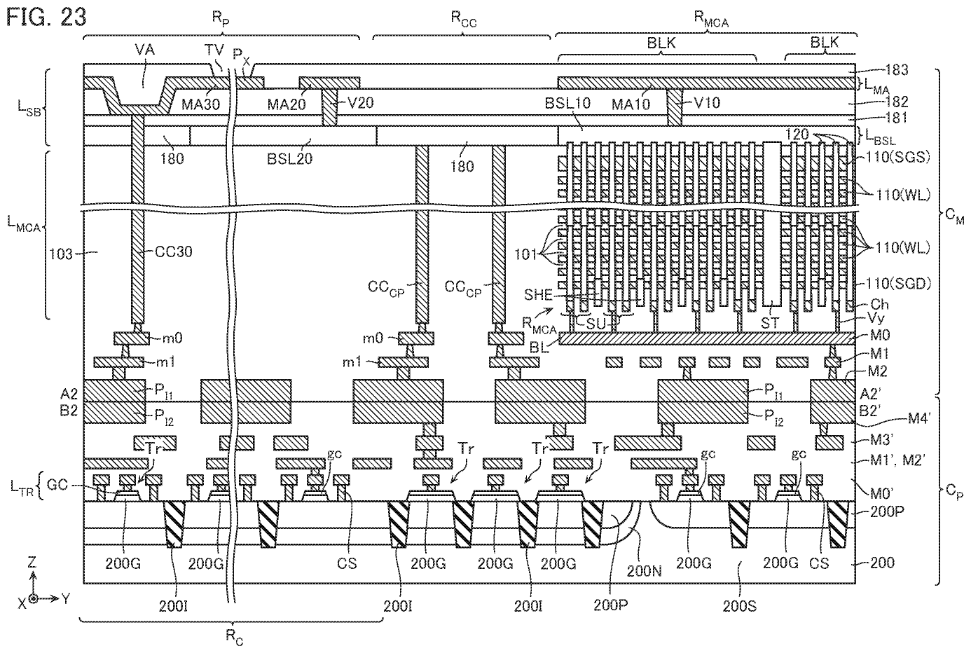

Next, with reference to FIG. 23, a semiconductor memory device according to the third embodiment is described. FIG. 23 is a schematic cross-sectional view illustrating a configuration of a part of the semiconductor memory device according to the third embodiment. In the following description, descriptions of the configuration similar to those in the first embodiment may be omitted.

The semiconductor memory device according to the embodiment is basically configured similarly to the semiconductor memory device according to the first embodiment. However, the semiconductor memory device according to the third embodiment includes a region R_{CC} disposed between the memory cell array region R_{MCA} and the peripheral region R_{P}.

As illustrated in FIG. 23, a plurality of contacts CC_{CP} are disposed in the region R_{CC}. The plurality of contacts CC_{CP} extend in the Z-direction, have upper ends connected to, for example, the insulating layer 180, have lower ends connected to, for example, the wirings m0 in the wiring layers M0, and are connected to the configuration in the chip C_{P} via the wirings m0, m1, and the like. The contact CC_{CP} may include, for example, a stacked film of a barrier conductive film, such as titanium nitride (TiN), and a metal film, such as tungsten (W), or the like.

Each of the plurality of contacts CC_{CP} may also function as a part of the capacitive element CP_{bp}, which is the bypass capacitor described with reference to FIG. 8. For example, two adjacent contacts CC_{CP} of the plurality of contacts CC_{CP} may function as one and the other electrodes of the capacitive element CP_{bp}. Respective two adjacent contacts CC_{CP} of the plurality of contacts CC_{CP} may be connected to the power supply terminals VSS, VCCQ via the wirings m0, m1, the first bonding electrodes P_{I1}, the configuration in the chip C_{P}, and the like. During operation of the semiconductor memory device, the ground voltage V_{SS} and the power supply voltage V_{CCQ} are applied to the plurality of contacts CC_{CP} via the power supply terminals VSS, VCCQ.

### Others

In the first to third embodiments, examples in which the capacitive element CP10, CP20, or the like is used as the bypass capacitor have been described. However, any capacitive element can be used as long as it is included in the peripheral circuit PC, and the capacitive element can be used for any capacitive element other than the capacitive element CP_{bp} described with reference to FIG. 8. For example, the capacitive element CP10, CP20, or the like can also be used for the capacitive element CP32a3 described with reference to FIG. 7. In the first to third embodiments, examples in which the capacitive element CP10, CP20, or the like is disposed in the peripheral region R_{P} have been described. However, the capacitive element CP10, CP20, or the like may be disposed in a region other than the peripheral region R_{P}, such as an outside of the hook-up region R_{HU} in the X-direction (FIG. 10).

In the first to third embodiments, the capacitive element CP10, CP20 or the like may be a parallel-plate capacitor. In this case, electrodes at one side and at the other side of the capacitive element CP10, CP20 or the like may be electrode plates at one side and at the other side of the parallel-plate capacitor.

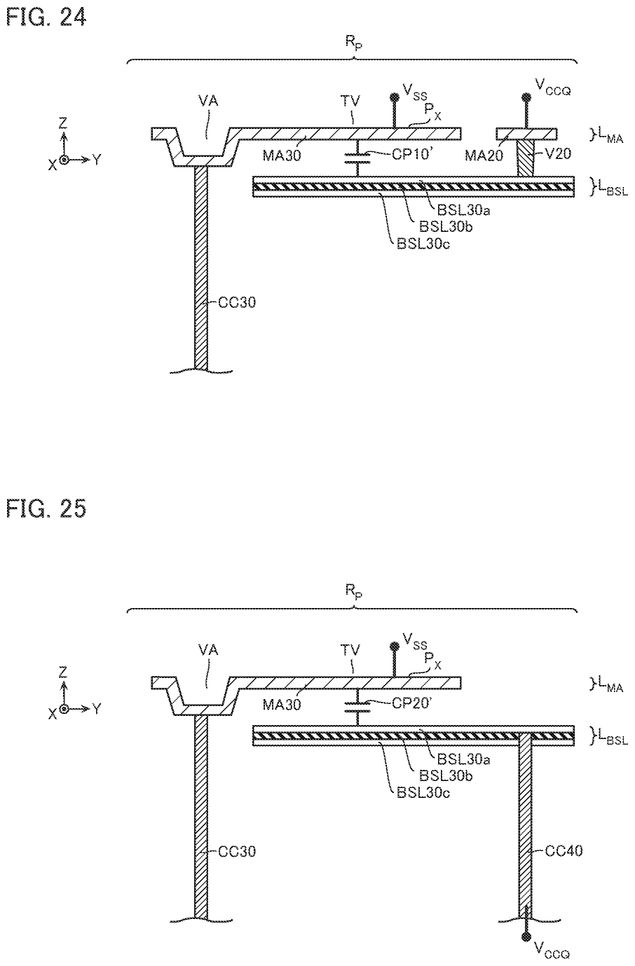

The capacitive element CP10 (FIG. 16) may be configured similarly to a capacitive element CP10′ illustrated in FIG. 24. In the wiring layer L_{BSL}, the capacitive element CP10′ includes a conductive layer BSL30a, an insulating layer BSL30b disposed below the conductive layer BSL30a, and a conductive layer BSL30c disposed below the insulating layer BSL30b, instead of the conductive layer BSL20. The conductive layer BSL30a and the conductive layer BSL30c are, for example, semiconductor layers of polycrystalline silicon (Si) or the like into which N-type impurities, such as phosphorus (P), or P-type impurities, such as boron (B), are implanted. The insulating layer BSL30b is, for example, an insulating layer of silicon nitride (Si₃N₄) or the like. In such a case, as illustrated in FIG. 24, the plurality of contacts V20 may be connected to the conductive layer BSL30a from above.

The capacitive element CP20 (FIG. 22) may be configured similarly to a capacitive element CP20′ illustrated in FIG. 25. Similarly to the capacitive element CP10′ (FIG. 24), in the wiring layer L_{BSL}, the capacitive element CP20′ includes the conductive layer BSL30a, the insulating layer BSL30b disposed below the conductive layer BSL30a, and the conductive layer BSL30c disposed below the insulating layer BSL30b, instead of the conductive layer BSL20. In such a case, as illustrated in FIG. 25, the plurality of contacts CC40 may be connected to the conductive layer BSL30a from below.

In the example illustrated in FIG. 10, the hook-up regions R_{HU} are disposed at both end portions of the memory cell array region R_{MCA} in the X-direction. However, the configuration is merely an example, and a specific configuration is appropriately adjustable. For example, the hook-up region R_{HU} may be disposed at one end portion of the memory cell array region R_{MCA} in the X-direction instead of both end portions in the X-direction. The hook-up region R_{HU} may be disposed at a center position or at a position close to a center of the memory cell array region R_{MCA} in the X-direction.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a first wiring layer including a first conductive layer and a second conductive layer;
a second wiring layer disposed between the substrate and the first wiring layer; and
a memory cell array layer disposed between the substrate and the second wiring layer, wherein
the memory cell array layer includes:
a plurality of third conductive layers arranged in a first direction intersecting with a surface of the substrate;
a semiconductor layer extending in the first direction and opposed to the plurality of third conductive layers; and
an electric charge accumulating layer disposed between the plurality of third conductive layers and the semiconductor layer, and
the second wiring layer includes:
a fourth conductive layer connected to one end portion of the semiconductor layer in the first direction; and
a fifth conductive layer opposed to the first conductive layer and electrically connected to the second conductive layer.

2. The semiconductor memory device according to claim 1, comprising
a first contact and a second contact disposed between the first wiring layer and the second wiring layer, wherein
the first wiring layer includes a sixth conductive layer,
the sixth conductive layer is connected to the fourth conductive layer via the first contact, and
the second conductive layer is connected to the fifth conductive layer via the second contact.

3. The semiconductor memory device according to claim 1, comprising
a first bonding pad, wherein
the second conductive layer includes the first bonding pad.

4. The semiconductor memory device according to claim 1, comprising
a second bonding pad, wherein
the first conductive layer includes the second bonding pad.

5. The semiconductor memory device according to claim 1, comprising
a capacitive element, wherein
the first conductive layer includes one electrode plate of the capacitive element, and
the fifth conductive layer includes the other electrode plate of the capacitive element.

6. The semiconductor memory device according to claim 1, comprising
a first chip and a second chip connected to one another, wherein
the first chip includes:
the memory cell array layer;
the first wiring layer disposed at one side in the first direction with respect to the memory cell array layer; and
a plurality of first bonding electrodes disposed at the other side in the first direction with respect to the memory cell array layer,
the second chip includes:
the substrate;
a plurality of transistors disposed on the surface of the substrate; and
a plurality of second bonding electrodes electrically connected to the plurality of transistors, and
the plurality of first bonding electrodes are connected to the plurality of second bonding electrodes.

7. The semiconductor memory device according to claim 1, wherein
the fourth conductive layer and the fifth conductive layer contain polycrystalline silicon.

8. The semiconductor memory device according to claim 1, wherein
the first conductive layer includes a portion overlapping the fifth conductive layer when viewed in the first direction.

9. The semiconductor memory device according to claim 1, wherein
the fourth conductive layer includes a portion overlapping the semiconductor layer when viewed in the first direction.

10. The semiconductor memory device according to claim 1, wherein
a first voltage is applied to one of the first conductive layer and the fifth conductive layer, and a second voltage larger than the first voltage is applied to the other of the first conductive layer and the fifth conductive layer.

11. A semiconductor memory device comprising:
a substrate;
a first wiring layer including a first conductive layer;
a second wiring layer disposed between the substrate and the first wiring layer; and
a memory cell array layer disposed between the substrate and the second wiring layer and including a cell array region and a peripheral region, wherein
the cell array region includes:
a plurality of third conductive layers arranged in a first direction intersecting with a surface of the substrate;
a semiconductor layer extending in the first direction and opposed to the plurality of third conductive layers; and
an electric charge accumulating layer disposed between the plurality of third conductive layers and the semiconductor layer,
the peripheral region includes a third contact and a fourth contact that extend in the first direction,
the second wiring layer includes:
a fourth conductive layer connected to one end portion of the semiconductor layer in the first direction; and
a fifth conductive layer opposed to the first conductive layer,
the first conductive layer is electrically connected to the third contact, and
the fifth conductive layer is electrically connected to the fourth contact.

12. The semiconductor memory device according to claim 11, comprising
a second bonding pad, wherein
the first conductive layer includes the second bonding pad.

13. The semiconductor memory device according to claim 11, wherein
the semiconductor memory device includes a capacitive element,
the first conductive layer includes one electrode plate of the capacitive element, and
the fifth conductive layer includes the other electrode plate of the capacitive element.

14. The semiconductor memory device according to claim 11, comprising
a first chip and a second chip connected to one another, wherein
the first chip includes:
the memory cell array layer;
the first wiring layer disposed at one side in the first direction with respect to the memory cell array layer; and
a plurality of first bonding electrodes disposed at the other side in the first direction with respect to the memory cell array layer,
the second chip includes:
the substrate;
a plurality of transistors disposed on the surface of the substrate; and
a plurality of second bonding electrodes electrically connected to the plurality of transistors, and
the plurality of first bonding electrodes are connected to the plurality of second bonding electrodes.

15. The semiconductor memory device according to claim 11, wherein
the fourth conductive layer and the fifth conductive layer contain polycrystalline silicon.

16. The semiconductor memory device according to claim 11, wherein
the first conductive layer includes a portion overlapping the fifth conductive layer when viewed in the first direction.

17. The semiconductor memory device according to claim 11, wherein
the fourth conductive layer includes a portion overlapping the semiconductor layer when viewed in the first direction.

18. The semiconductor memory device according to claim 11, wherein
a first voltage is applied to one of the first conductive layer and the fifth conductive layer, and a second voltage larger than the first voltage is applied to the other of the first conductive layer and the fifth conductive layer.
